(19) United States
(12) Patent Application Publication
(10) Pub. No.: US 2018/0317314 A1
(43) Pub. Date: Nov. 1, 2018

(54) Object Made of a Folded Sheet with Printed Electric Controls

(71) Applicant: Universität des Saarlandes, Saarbrücken (DE)

(72) Inventors: Simon Olberding, Saarbrücken (DE); Jürgen Steimle, Saarbrücken (DE)

(73) Assignee: Universität des Saarlandes, Saarbrücken (DE)

(21) Appl. No.: 15/770,114

(22) PCT Filed: Oct. 24, 2016
(86) PCT No.: PCT/EP2016/075583

§ 371 Date: Apr. 20, 2018

(30) Foreign Application Priority Data
Oct. 23, 2015 (EP) 15191170.8

(51) Int. Cl. H05K 1/02; H05K 1/11; H05K 1/16; G06T 19/00; G06F 3/044

(52) U.S. Cl. CPC H05K 1/028; H05K 1/11; H05K 2201/0145; G06T 19/00; G06F 3/044; H05K 1/162

(57) ABSTRACT

The invention is directed to an object (2) with a three-dimensional shape made of a folded sheet (4) so as to form at least one face (6), at least one corner (10) and/or at least one edge (8), the object comprising electrically conductive traces (14) printed on the sheet (4); and at least one functional area (12) printed on one of the at least one face (6), adjacent to one of the at least one edge (8), or adjacent to one of the at least one corner (10), the at least one functional area (12) being electrically connected to the conductive traces (14) and forming at least one control for a touch input, for a display output, and/or for sensing a change of shape of the object.

### TECHNICAL FIELD

The invention is directed to the field of tri-dimensional objects made by folding a sheet of material.

### BACKGROUND ART

Publication of Felton, S. M., Tolley, M. T., Shin, B., Onal, C. D., Demaine, E. D., Rus, D. and Wood, Robert J.: “Self-folding with shape memory composites”, Soft Matter 9, no. 32 (2013), discloses a self-folding sheet for obtaining a three-dimensional object. The self-folding principle is based on the use of a layer of shape memory polymer (SMP) bonded to a substrate at a location where the substrate is provided with a score line. An electrically conductive and resistive path or trace on a polyimide sheet is sandwiched between the SMP layer and the substrate. Upon supply of the resistive path with electrical energy, the heat produced changes the shape of the SMP layer which then folds the substrate along the score line. The purpose of this solution is for producing origami-inspired objects, supposed to be a more efficient alternative to three-dimensional printing and traditional manufacturing. SMP layers are however expensive and the self-folding can become unreliable for complicated shapes.

Publication of Sung, C., Rus, D.: “Foldable joints for foldable robots”, Journal of Mechanisms and Robotics, 2015, discloses robots made by folding a substrate and providing foldable joints. A control circuitry can be printed on the sheet and actuators can be provided for actuating the joints. This document demonstrates the feasibility of manufacturing an entire robot in one uniform process via print-and-fold. An example of robot that can be manufactured by this method is a camera mount. It becomes however unstable when large displacements are attempted. In addition, the manufacturing remains complex, in particular when mounting the actuators.

The above references show that objects of a reduced size can be manufactured by folding a sheet of material and that electrically conductive traces can be printed thereon for providing additional functions, like self-folding or electrically supplying actuators. Such objects remain however rather fragile and therefore limited essentially to an ornamental use.

### SUMMARY OF INVENTION

### Technical Problem

The invention has for technical problem to overcome at least one of the drawbacks of the above cited prior art. More specifically, the invention has for technical problem to enhance the functionality of interactive folded objects.

### Technical solution

The invention is directed to an object with a three-dimensional shape made of a folded sheet so as to form at least one face, at least one corner and/or at least one edge, the object comprising electrically conductive traces printed on the sheet; wherein the object further comprises at least one functional area printed on one of the at least one face, and/or adjacent to one of the at least one edge, and/or adjacent to one of the at least one corner, the at least one functional area being electrically connected to the conductive traces and forming at least one control for a touch input, for a display output, and/or for sensing a change of shape of the object.

The sheet is such that it can be folded.

According to a preferred embodiment, at least one of the at least one functional area forms a capacitive electrode.

According to a preferred embodiment, the, or each of the, at least one functional area forms a capacitive electrode located on a central area of one of the at least one face.

According to a preferred embodiment, the at least one functional area comprises at least two electrodes adjacent to each other so as to form a capacitive touch control.

According to a preferred embodiment, the at least two electrodes adjacent to each other are located on opposite sides, respectively, of one of the at least one edge.

According to a preferred embodiment, the at least two electrodes adjacent to each other comprise at three, preferably at least four, of said electrodes, distributed around one of the at least one corner, the corner being formed by an intersection of at least three of the at least one edge, the electrodes being distributed between the edges around the corner.

According to a preferred embodiment, the electrodes distributed around the corner form a rotary touch control.

According to a preferred embodiment, the at least two electrodes adjacent to each other extend each on opposite sides of one of the at least one edge.

According to a preferred embodiment, the at least two electrodes adjacent to each other comprise at least three, preferably at least four, of said electrodes, distributed along the edge so as to form a touch slider control.

According to a preferred embodiment, the at least two electrodes adjacent to each other are distant from each other adjacently by less than 5 mm, preferably 4 mm, more preferably 3 mm.

According to a preferred embodiment, at least one of the at least one functional area forms an electrically luminescent area.

According to a preferred embodiment, the at least one functional area comprises at least two electrodes adjacent to each other on either sides of one of the at least one edge so as to form a capacitive sensing control of a relative position between the electrodes.

According to a preferred embodiment, the object comprises at least one movable part on at least one of the sides of the edge with the capacitive sensing control.

According to a preferred embodiment, the movable part of the object forms a lid, a cover, a wall or a bellow of the object.

According to a preferred embodiment, the sheet is made of paper with an inner side and an outer side, the conductive traces and the at least one functional area are printed on an inner side.

According to a preferred embodiment, the at least one functional area is electrically connected via the conductive traces to a microcontroller, said microcontroller being preferably arranged on the inner side of the sheet.

The invention has also for object a method for manufacturing an object according to the invention, comprising the following steps: providing the sheet; printing a two-dimensional pattern of the object and the functional areas for the electronic control on the sheet; cutting the two-dimensional pattern out of the sheet; folding the two-dimensional pattern so as to form the three-dimensional object with the at least one control.

According to a preferred embodiment, the method comprises the following steps before the steps of providing and printing the sheet: providing a three-dimensional model of the object in a memory element of a computing device; selecting at least one region on the three-dimensional model for inclusion of an electronic control; generating, using computer means, a two-dimensional folding pattern which, when folded, is equivalent to the object represented by the three-dimensional pattern; identifying, using computer means, at least one location on the two-dimensional folding pattern which corresponds to the at least one region specified on the three-dimensional model.

### Advantages of the invention

The invention is particularly interesting in that it provides a rapid, economic and intuitive fabrication pipeline for generating interactive objects where the interactivity can be particularly enhanced by touch control(s), visual display control(s) and/or sensing control(s) such as shape change sensing controls. The controls can be easily printed on the two-dimensional sheet forming the fold pattern of the three-dimensional object. The electrically conductive traces can extend across fold edges.

### BRIEF DESCRIPTION OF THE DRAWINGS

FIG. 1 illustrates an unfolded and a folded shape of an object illustrating the possible locations of controls according to the invention.

FIG. 2 illustrates various locations and constructions of controls on a folded object according to the invention.

FIG. 3 illustrates a folded object according to a first embodiment of the invention.

FIG. 4 illustrates a folded object according to a second embodiment of the invention.

FIG. 5 illustrates a folded object according to a third embodiment of the invention.

FIG. 6 illustrates various folded object according to a fourth embodiment of the invention

### DESCRIPTION OF AN EMBODIMENT

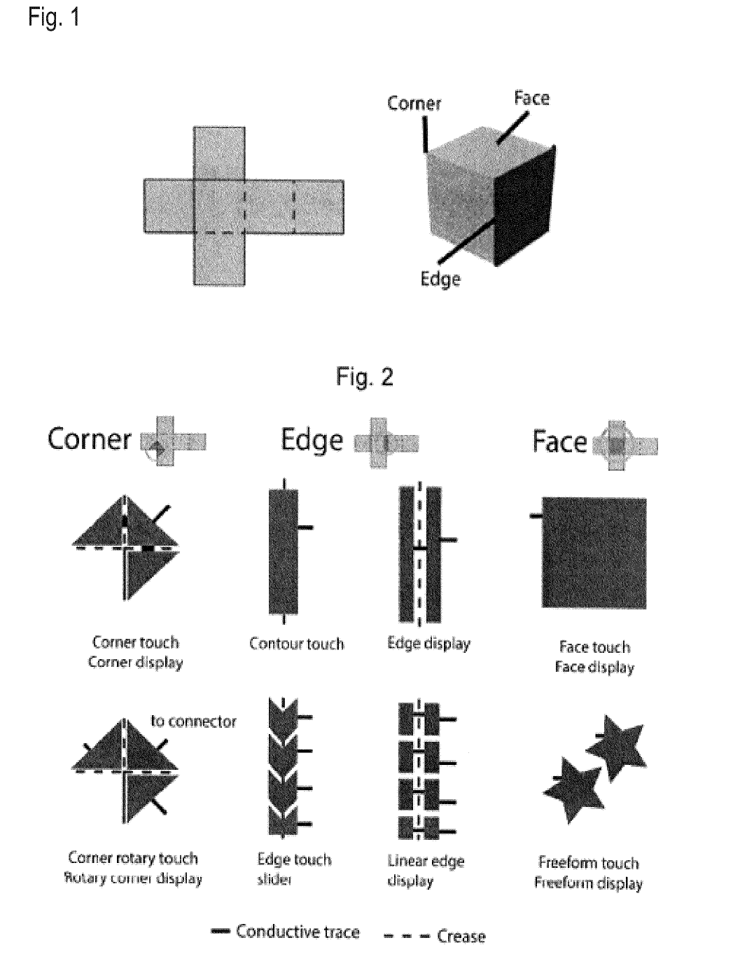

FIG. 1 illustrates a simple foldable object, for instance a cube, in an unfolded and folded state. The illustration in the folded state shows the location of one of the faces, as well as one of the edges and one of the corners. As is apparent, the edge results from the fold line between two faces and the corner is the point of intersection of three edges. According to the invention, electric controls are printed on a two-dimensional sheet of an object prior folding, at the locations illustrated in FIG. 1.

Various established printing method exist, like inkjet printing, using a fully automated off-the-shelf printer, and also screen printing. Inkjet printing can be used for printing single-layer areas like electrodes whereas screen printing can be used for multi-layer areas like light emitting areas.

It can be advantageous to first fold and unfold the substrate once before printing on it; this makes conductors more robust to folding. To ensure instant inkjet printouts are robust, it can be advantageous to patch conductive traces that go across folds with copper tape. Screen-printed conductors are more robust and need to be patched only if heavily used during continuous shape changing.

Light emitting areas can be technically realized through thin-film electroluminescent light-emitting displays. These are printed onto the foldable sheet using screen printing. In contrast to electrodes, which require only one layer of conductor, light emitting areas are printed with four layers. It is referred to the publication of Olberding, S., Wessely, M., and Steimle, J.: “PrintScreen: fabricating highly customizable thin-film touch-displays”, In Proc. of UIST '14.

FIG. 2 illustrates various types of controls that can be printed on the two-dimensional sheet prior folding. In the eight main illustrations of FIG. 2, the dark areas illustrate functional areas that are printed in the sheet of the object. These areas can be electrodes and/or electrically illuminating (i.e. light emitting) areas as described here above. The continuous lines correspond to conductive traces (except for the vertical lines in the left part “Corner” of the figure) whereas the dotted lines correspond to fold or crease lines of the object.

In FIG. 2, the left part illustrates controls on a corner of a foldable object. A corner control is realized by providing a touch sensing electrode on each neighbouring face of a given corner. For a simple touch corner control, as illustrated in the upper left drawing (“Corner touch/Corner display”), all electrodes can be electrically connected to each other whereas for a rotary touch corner control, as illustrated in the lower left drawing (“Corner rotary touch/Rotary corner display), each electrode is separately connected and read out. With reference to the above discussion about the construction of the functional areas, these can be display controls instead of, or in addition to, touch controls.

Capacitive touch sensing controls can be taken from the Arduino CapSense Library.

The central part of FIG. 2 illustrates controls on an edge of a foldable object. In the upper left drawing (“Control touch”) of the central part, a touch sensing control is provided on an edge using a single electrode which extends to both sides across the edge. For an enhanced touch control able to detect a sliding touch movement, the functional area can comprise several juxtaposed electrodes distributed along the edge, as illustrated in the lower left drawing (“Edge touch slider”) of the central part of FIG. 2. As is apparent, each electrode is separately connected to a specific electrically conductive trace so that the microcontroller to which it is connected can detect the sliding touch movement.

Still in the central part of FIG. 2, the upper right drawing (“Edge display”) and the lower right drawing (“Linear edge display”) illustrate two types of display controls on the edge of the foldable object. The first one comprises for instance two light-emitting areas arranged on either sides of the edge and are electrically connected so as to be supplied together with electrical energy. The second one comprises a series of juxtaposed areas on either sides of the edge and distributed along said edge. As is apparent in the drawing, each pair of areas arranged in vis-à-vis relative to the edge are electrically connected, similarly to the above first type of display control located on an edge, whereas each pair is independently connected to a microcontroller so as to provide an enhance display effect, like for example a progressive lighting along the edge.

The right part of FIG. 2 illustrates controls on a face of the foldable object. The controls can be touch controls and/or display controls. The upper drawing (“Face touch/Face display”) of the right part of FIG. 2 illustrates a functional area that covers a major portion of the face, for instance the entire face. The lower drawing (“Freeform touch/Freeform display”) illustrates two distinct functional areas each with a freeform and both located on the same face of the object. With reference to the above discussion about the construction of the functional areas, these can be display controls instead of, or in addition to, touch controls.

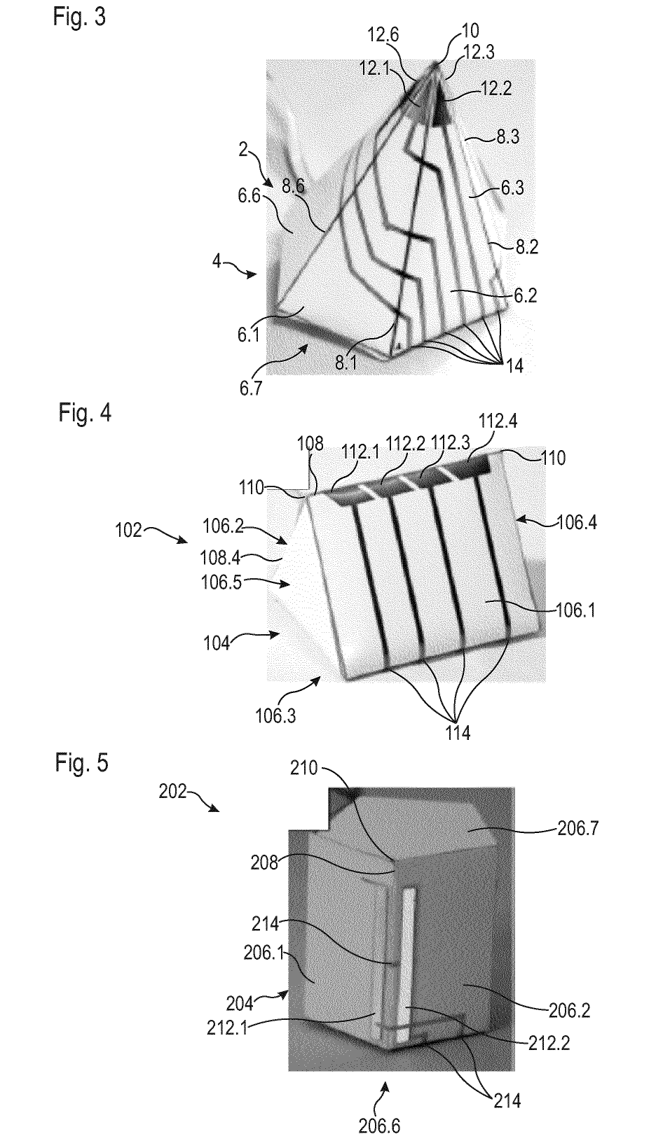

FIG. 3 illustrates an interactive folded object according to a first embodiment of the invention. The object 2 is made by folding a sheet 4 made for instance essentially of paper, being understood that other materials or material combinations are possible. The object 2 has general shape of a pyramid with a hexagonal base. It comprises six triangular faces 6.1 . . . 6.6, a base face 6.7, six fold edges 8.1 . . . 8.6 and a corner 10. The faces 6.4 and 6.5, as well as the edges 8.4 and 8.5 are not visible. The object 2 comprises functional areas 12.1 to 12.6 printed on the sheet 4 around the corner 10. These areas are for instance electrodes, i.e. electrically conductive areas. Each of these areas is separately electrically connected to a specific trace 14 for operating the resulting rotary touch control. In this FIG. 3, the electrodes 12.1 to 12.6 and electrically conductive traces 14 are illustrated on the outer side of the sheet 4 for the sake of illustration, these being advantageously on the inner side.

The touch control at the corner 10 of the object 2 in FIG. 3 is a rotary touch control in that it can detect not only a simple contact by one of several fingers but also a rotation of one or several fingers around the corner. This provides an enhanced control that can for example control the level of operation of an electrically operated function, like a lightning function.

It can be observed in FIG. 3 that the electrically conductive traces 14 can cross through at least several of the fold edges 8.1 to 8.6. The folding operation keeps the integrity of the traces so that they remain conductive when passing across an edge. The traces 14 can be connected to an electronic chip (not visible), e.g. of the microcontroller type, that can be arranged directly on the sheet.

FIG. 4 illustrates an interactive folded object according to a second embodiment of the invention. The reference numbers of the first embodiment are used here for designating the same or corresponding elements, these numbers being however incremented by 100. It is also referred to the description of these elements in relation with the first embodiment.

The shape of the object 102 in FIG. 4 is a polyhedron with a triangular cross-section. It comprises three rectangular faces 106.1, 106.2 and 106.3 (not visible) and two triangular faces 104.4 (not visible) and 106.5. It comprises a series of fold edges between these faces. The top edge 108 is provided with a slider touch control comprising for instance four electrodes 112.1 to 112.4. Each of these electrodes extends on either sides of the edge 108 and is separately connected via a specific conductive trace 114. Similarly to FIG. 3, the electrodes 112.1 to 112.4 and the electrically conductive traces 114 are illustrated on the outer side of the sheet 104 for the sake of illustration, these being advantageously on the inner side.

It can be observed in FIG. 4 that the electrically conductive traces 114 can cross through at least one of the fold edges. The folding operation keeps however the integrity of the traces so that they remain conductive when passing across an edge. The traces 114 can be connected to an electronic chip (not visible), e.g. of the microcontroller type, that can be arranged directly on the sheet.

The touch control at the edge 108 of the object 102 in FIG. 4 is a slider touch control in that it can detect not only a simple contact by one of several fingers but also a sliding movement of said finger(s).

FIG. 5 illustrates an interactive folded object according to a third embodiment of the invention. The reference numbers of the first embodiment are used here for designating the same or corresponding elements, these numbers being however incremented by 200. It is also referred to the description of these elements in relation with the first embodiment.

The shape of the object 202 in FIG. 5 is a polyhedron with a pentagon base. It comprises five rectangular faces 206.1 to 206.5 where only faces 206.1 and 206.2 are visible. It comprises also two pentagonal faces 206.6 and 206.7. It comprises a series of fold edges between these faces, comprising the edge 208 between the two faces 206.1 and 206.2. Light-emitting functional areas 212.1 and 212.2 are provided on these faces, respectively, on either sides of the edge 208. Each of these areas 212.1 and 212.2 is configured for emitting light when being supplied with electrical energy. Similarly to FIGS. 3 and 4, the areas 212.1 and 212.2 and the electrically conductive traces 214 are illustrated on the outer side of the sheet 204 for the sake of illustration, these being advantageously on the inner side. As is apparent in FIG. 5, these two areas are electrically connected in series by the conductive traces 214. This means that they are lit together. It is however to be understood that these areas can be electrically powered independently.

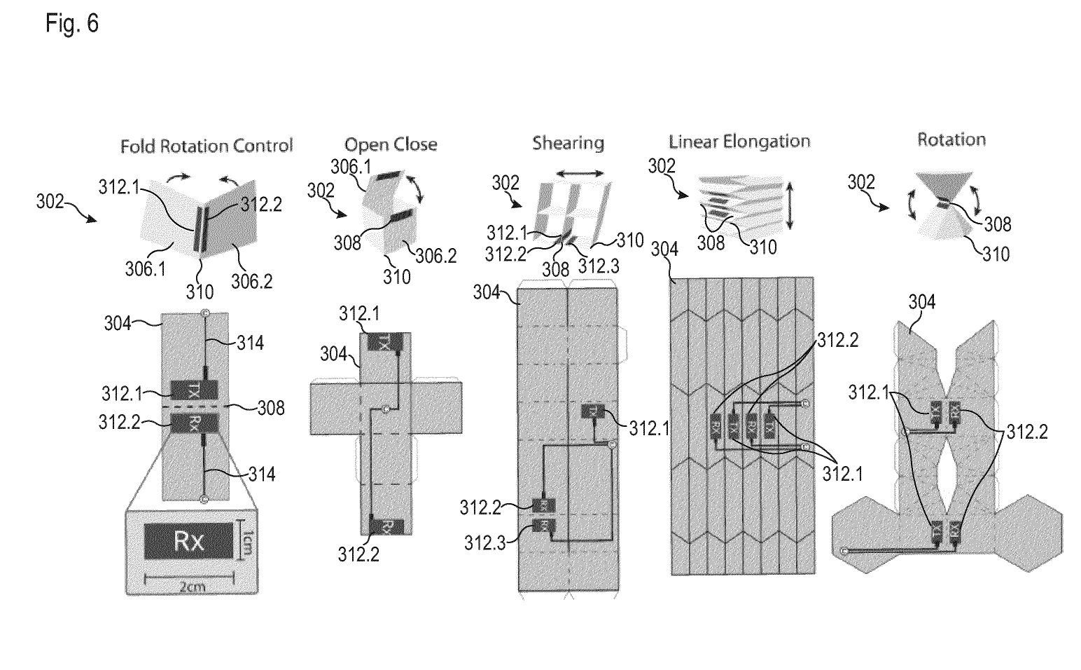

FIG. 6 illustrates five variants of an interactive folded object according to a fourth embodiment of the invention. The reference numbers of the first embodiment are used here for designating the same or corresponding elements, these numbers being however incremented by 300. It is also referred to the description of these elements in relation with the first embodiment. In that embodiment, objects are configured so as to be able to change their shape by a folding action. Also, the functional areas are shape sensing controls, i.e. controls that sense a change of shape of the object.

In the first part “Fold Rotation Control” of FIG. 6, the first variant object 302 comprises two faces 306.1 and 306.2 formed in the sheet 304 and delimited relative to each other by a fold edge 308. Two functional areas 312.1 and 312.2 are printed on the two faces 306.1 and 306.2, respectively, on either sides of the edge 308. The ability of these functional areas, designed as electrodes, to sense a change of shape is based on a change of capacitance of the capacitor formed by these electrodes during the change of shape. The electrodes are placed on opposite sides of the edge 308 at a reduced distance (e.g. less than 4 mm). An AC signal (e.g. 10 Khz, at 10 V) is applied on the transmitting electrode 312.1 (Tx). The strength of the signal on the receiving electrode 312.2 (Rx) allows the angle to be inferred. To allow the control to measure angles larger than 180°, another electrode pair can optionally be printed on the reverse side. In this case, electrode pairs are displaced, e.g. by at least 2 cm, along the edge to reduce capacitive crosstalk. The shape sensing control works accurately if the user is not touching any of the electrodes nor interacting with hands or fingers in a reduced distance, e.g. 3 mm or less, from the electrodes. The influence of capacitive noise can be decreased by printing multiple redundant emit-and-receive pairs at different locations. In addition, the sensor could actively identify if a finger is touching an electrode by time multiplexing between a touch sensing cycle and an angle sensing cycle. If touch contact is detected, the value from angle sensing is then flagged as compromised. While the capacitive approach might not ideal for applications that require highly accurate sensing, it provides reasonable accuracy for many practical applications in packaging, paper crafts and prototyping. These applications leverage on the simple printability of the sensor, its slim form factor and its mechanical robustness.

Emitting and receiving sensing electrodes can be implemented on a Picotech oscilloscope.

The second part “Open Close” of FIG. 6 illustrates a second variant of the fourth embodiment of the invention. The electrodes 312.1 and 312.2 of the shape sensing control are arranged on either sides of an edge 308 that forms an opening. This edge 308 is not a fold edge but well an edge where the face 306.1, upon folding, can move towards or away from the face 306.2. The shape sensing control forms then an open/close sensor.

The third part “Shearing” of FIG. 6 illustrates a third variant of the fourth embodiment of the invention. Shearing is sensed by three electrodes on the folded object 302. Two receiving electrodes 312.2 and 312.3 capture the signal of the transmitting electrode 312.1.

The fourth part “Linear Elongation” of FIG. 6 illustrates a fourth variant of the fourth embodiment of the invention. In that variant, the object is bellow folded and comprises at least one pair of transmitting and receiving electrodes 312.1 and 312.2 on either sides of a fold edge 308. For instance, the object comprises two such pairs on two adjacent fold edges. Thanks to such a construction, the linear elongation of the object can be easily detected.

The fifth part “Rotation” of FIG. 6 illustrates a fourth variant of the fourth embodiment of the invention. In that variant, the object 302 is shaped such as to show a joint edge 308 that allows two portions of the object to pivot relative to each other. At least one pair of transmitting and receiving electrodes 312.1 and 312.2 is placed on either sides of the joint fold edge 308.

The high stiffness-to-weight ratio of folded objects enables the fabrication of hollow objects. This makes such objects well suited for smart packaging. For an interactive box made of cardboard can be constructed similarly to the second variant of FIG. 6. It senses when its lid is opened or closed using the open/close control. The design and manufacturing are easy, rapid and cheap. Perceptible contours can be easily funtionalized by intuitive controls such as rotational knobs (on corners) or slides (on edges). Another example of interactive object is a lamp shade. The user can touch the lamp shade to switch a digitally controlled light bulb inside the lamp on and off. Sliding along an edge dims the lamp. The lamp shade can be fabricated by screen printing a 2D layout with translucent conductive ink on a translucent PET sheet (e.g. of 0.5 mm thickness). Custom-shaped foldable objects with input and output controls enables quick and easy fabrication of devices that act as specific controllers or provide computer output. As one example, a game controller that makes use of a rotation control as in the fifth variant of FIG. 6 can be manufactured.

For creating an interactive foldable object according to the invention, the designer can start by creating a 3D model of the object in a CAD modelling environment. The designer can model the foldable object in 3D, like any standard 3D object, and define interactive behaviour with high-level user interface controls. The designer can for example first select a 3D element (e.g., an edge) that should become interactive. Then, he can assign the interactive behaviour (e.g., a touch sensitive slider). A control can be assigned to a corner, edge and/or face of the 3D model with a single click. Interactive user interfaces can be selected by means of a Python add-on for Blender, a free and widely used 3D modelling suite. As a result, the designer can use Blender's powerful built-in functionality for modelling the object.

Next, the modelling software automatically generates a two-dimensional print-and-fold layout for the foldable object. An unfolding algorithm based on region growing can be used. To work correctly, the algorithm might require a three-dimensional geometry that has only planar faces. If the three-dimensional model contains curved faces (e.g. a sphere), the designer can use Blender's built-in functionality to triangulate the face. The result of the unfolding step is a two-dimensional crease pattern with gluing flaps, which however does not yet contain the layout for printable electronics yet. In a subsequent step, the above algorithm adds layouts for printable electronics to the two-dimensional crease pattern. Interactive controls which the designer has added to the three-dimensional model can be stored as annotations of the three-dimensional model, indicating the type of control and its parameters. The algorithm sequentially processes these annotations and accounts for several parameters: geometric constraints (location, size and shape of the control), the desired resolution of the component, and electronic constraints (min. and max. dimensions and distances between electrodes). The unfolding process may require splitting up the pattern at an edge to flatten it. Each control, that is located on this edge or extends over it, can be split into two separate parts. These are reconnected across the fold: the algorithm generates two gluing flaps, one on each slide, containing a conductive pin for each electrode. When the object is folded, a conductive connection between these pins can be realized by using double-sided conductive adhesive tape (z-tape by 3M). Lastly, the algorithm automatically creates conductive traces that connect each electrode with a connector area, where the microcontroller is connected. As folding introduces high mechanical stress at the folds, conductive traces are generated with 2 mm width. Commercially available algorithms for printed circuit board (PCB) layout can be used.

After printing the designer can manually folds the flat sheet to its three-dimensional shape. Many crease patterns require parts of the sheet to be cut off before folding. As an alternative to manual cutting, the sheet can be cut automatically with a laser cutter using the auto-generated outline graphic.

1-18. (canceled)

19. Object with a three-dimensional shape made of a folded sheet so as to form at least one face, at least one corner and/or at least one edge, the object comprising:
electrically conductive traces printed on the sheet; and
at least one functional area printed on one of the at least one face, adjacent to one of the at least one edge, or adjacent to one of the at least one corner, the at least one functional area being electrically connected to the conductive traces and forming at least one control for a touch input, for a display output, and/or for sensing a change of shape of the object.

20. Object according to claim 19, wherein at least one of the at least one functional area forms a capacitive electrode.

21. Object according to claim 20, wherein the, or each of the, at least one functional area forms a capacitive electrode located on a central area of one of the at least one face.

22. Object according to claim 19, wherein the at least one functional area comprises:
at least two electrodes adjacent to each other so as to form a capacitive touch control.

23. Object according to claim 22, wherein the at least two electrodes adjacent to each other are located on opposite sides, respectively, of one of the at least one edge.

24. Object according to claim 22, wherein the at least two electrodes adjacent to each other comprise:
at least three of said electrodes, distributed around one of the at least one corner, the corner being formed by an intersection of at least three of the at least one edge, the electrodes being distributed between the edges around the corner.

25. Object according to claim 24, wherein the electrodes distributed around the corner form a rotary touch control.

26. Object according to claim 22, wherein the at least two electrodes adjacent to each other extend each on opposite sides of one of the at least one edge.

27. Object according to claim 22, wherein the at least two electrodes adjacent to each other comprise:
at least three of said electrodes, distributed along the edge so as to form a touch slider control.

28. Object according to claim 22, wherein the at least two electrodes adjacent to each other are distant from each other adjacently by less than 5 mm.

29. Object according to claim 19, wherein at least one of the at least one functional area forms an electrically luminescent area.

30. Object according to claim 19, wherein the at least one functional area comprises:
at least two electrodes adjacent to each other on either sides of one of the at least one edge so as to form a capacitive sensing control of a relative position between the electrodes.

31. Object according to claim 30, further comprising:
at least one movable part on at least one of the sides of the edge with the capacitive sensing control.

32. Object according to claim 31, wherein the movable part of the object forms a lid, a cover, a wall or a bellow of the object.

33. Object according to claim 19, wherein the sheet is made of paper with an inner side and an outer side, the conductive traces and the at least one functional area are printed on an inner side.

34. Object according to claim 19, wherein the at least one functional area is electrically connected via the conductive traces to a microcontroller, said microcontroller being preferably arranged on the inner side of the sheet.

35. Method for manufacturing an object with a three-dimensional shape made of a folded sheet so as to form at least one face, at least one corner and/or at least one edge, the object comprising:
electrically conductive traces printed on the sheet; and
at least one functional area printed on one of the at least one face, adjacent to one of the at least one edge, or adjacent to one of the at least one corner, the at least one functional area being electrically connected to the conductive traces and forming at least one control for a touch input, for a display output, and/or for sensing a change of shape of the object;
the method comprising:
providing the sheet;
printing a two-dimensional pattern of the object and the at least one functional area for the electronic control on the sheet;
cutting the two-dimensional pattern out of the sheet; and
folding the two-dimensional pattern so as to form the three-dimensional object with the at least one control.

36. Method according to claim 35, comprising the following steps before the steps of providing and printing the sheet:
providing a three-dimensional model of the object in a memory element of a computing device;
selecting at least one region on the three-dimensional model for inclusion of an electronic control;
generating, using computer means, a two-dimensional folding pattern which, when folded, is equivalent to the object represented by the three-dimensional pattern; and
identifying, using computer means, at least one location on the two-dimensional folding pattern which corresponds to the at least one region specified on the three-dimensional model.
